(19) United States
(12) Patent Application Publication
(10) Pub. No.: US 2007/0281432 A1
(43) Pub. Date: Dec. 6, 2007

(54) Transistor and method of providing interlocking strained silicon on a silicon substrate

(76) Inventors: Matthias Goldbach, Dresden (DE); Thomas Hecht, Dresden (DE)

Correspondence Address: SLATER & MATSIL LLP, 17950 PRESTON ROAD, SUITE 1000, DALLAS, TX, 75252, US

(21) Appl. No.: 11/443,501

(22) Filed: May 30, 2006

(51) Int. Cl. H01L 21/336

(52) U.S. Cl. 438/301

(57) ABSTRACT

A method for providing interlocking strained silicon on a silicon substrate, comprises providing a mask on a surface of the substrate. The mask comprises a first plurality of openings corresponding to a first plurality of holes to be etched and comprises a second plurality of openings corresponding to a second plurality of holes to be etched. The surface of the substrate is etched through the mask to form the first and second pluralities of holes. A first strain type material is deposited into the first plurality of holes to form a plurality of first strain type portions. A plurality of second strain type portions are formed at the second plurality of holes.

### TECHNICAL FIELD

The present invention relates generally to semiconductor devices, and in a particular embodiment to a transistor and method of providing interlocking strained silicon on a silicon substrate.

### BACKGROUND

Using strained silicon may improve the performance of some semiconductor devices. For example, strained silicon may improve the performance of an inverter, for example a pFET/nFET pair (p channel field effect transistor/n channel field effect transistor). The performance of an nFET may be improved by providing tensile strain in the silicon below a shallow trench isolation (STI) trench in a direction perpendicular to and parallel with the gate. In the case of a pFET, performance may be improved by providing tensile strain of the silicon below an STI trench in a direction perpendicular with the gate and compressive strain in a direction parallel with the gate.

### SUMMARY OF THE INVENTION

In a first embodiment, a transistor includes a silicon substrate. A trench portion is formed at a surface of the silicon substrate. The substrate includes a first strain type portion oriented in a first direction and a second strain type portion oriented in a second direction.

### BRIEF DESCRIPTION OF THE DRAWINGS

Features and advantages of the invention may be readily appreciated by persons skilled in the art from the following detailed description of exemplary embodiments thereof, as illustrated in the accompanying drawings, in which:

FIG. 1 illustrates an exemplary embodiment of an inverter;

FIG. 2 illustrates an exemplary embodiment of a method for fabricating transistors;

FIG. 3 illustrates an exemplary embodiment of a method for fabricating transistors; and

FIGS. 4A-4I illustrate cross-sectional views of an exemplary embodiments of a silicon substrate.

### DETAILED DESCRIPTION OF ILLUSTRATIVE EMBODIMENTS

In the following detailed description and in the several figures of the drawing, like elements are identified with like reference numerals.

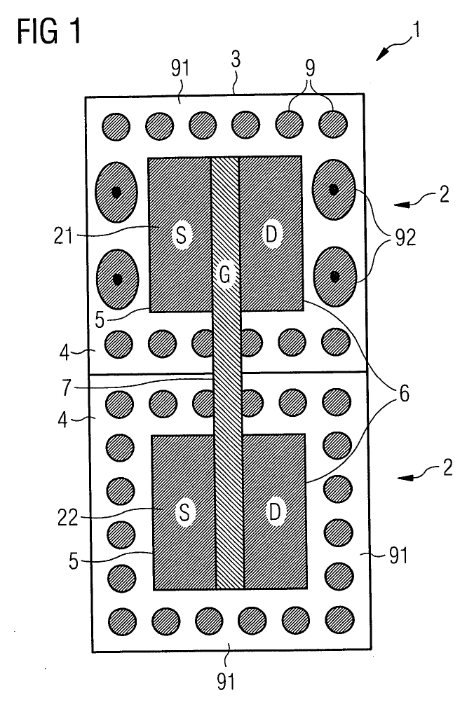

FIG. 1 illustrates an exemplary embodiment of an inverter 1. In an exemplary embodiment, the inverter 1 may include two MOSFET transistors 2. In an exemplary embodiment, the transistors 2 may be formed on a substrate 3, for example a silicon substrate. In an exemplary embodiment, the pair of transistors 2 may be a switch. Furthermore, the pair of transistors 2 may be an inverter.

In an exemplary embodiment, each transistor 2 may have a shallow trench isolation (STI) trench 4. In an exemplary embodiment, the trench 4 may be formed in a surface of the silicon substrate 3. In an exemplary embodiment, the trench 4 may be about 30 nm to about 350 nm wide and have an aspect ratio of approximately 1 to 200 or have a width in a range from about 100 nm to about 200 nm and an aspect ratio in a range from about 10 to about 100.

In an exemplary embodiment, each transistor 2 may have a source portion 5 and a drain portion 6. In an exemplary embodiment, each transistor 2 may have a gate 7 between the source 5 and the drain 6 portions. In an exemplary embodiment, the source, drain and gate may be fabricated using thin film production technology or methods.

The substrate 3, on which the inverter 1 may have been formed, may include strained silicon portions 9, for example, interlocking strained silicon portions. In an exemplary embodiment, the interlocking strained silicon portions may be located under the shallow trench isolation (STI) trenches 4 for their respective transistors 2 of the inverter 1.

In an exemplary embodiment, the inverter 1 may include transistors 2 of a first type 21 and a second type 22. In an exemplary embodiment, the first type may be a pFET transistor 21 and the second type may be an nFET transistor 22, for example, the first type may be a p MOS FET transistor 21 and the second type may be an n MOS FET transistor 22 (MOS: Metal Oxide Semiconductor).

The interlocking strained silicon portions 9 of the first type of transistor 21 may include at least one strain type portion 91 aligned in a first direction and a second strain type portion 92 aligned in an orthogonal direction, for example at about a 90 degree angle. It should be noted that the orthogonal direction may comprise a direction in two dimension, i.e., an orthogonal direction that is in a plane that is parallel to the main surface of the substrate 3 or in an orthogonal direction that is in a plane perpendicular to the main surface of the substrate 3. In an exemplary embodiment, the first strain type portion 91 may be tensile strain portion 91 and the second strain type portion 92 may be a compressive strain portion 92.

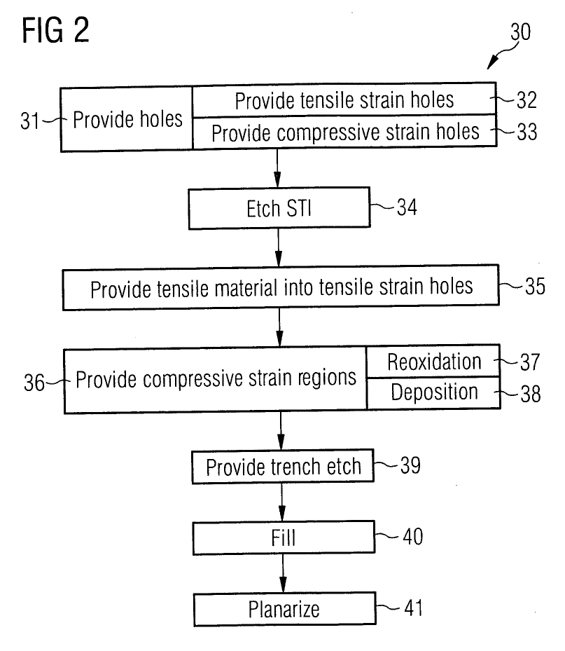

The strained portions 9, 91, 92 may be formed in holes etched into the silicon. In an exemplary embodiment, the portions may be formed by exemplary methods similar to those described and discussed below with respect to FIGS. 2, 3 and 4A to 4H.

In an exemplary embodiment, the STI trench 4 may have an arbitrary cross section, e.g., the cross section of a polygon, for example a quadrilateral or square cross section. In an exemplary embodiment, the gate portion 7 may run parallel with two of the STI sides and approximately perpendicular with the other two STI sides.

In an exemplary embodiment, the STI trench of a transistor may be about 200 nm to several μm, e.g., about 200 nm to 400 nm, long depending on the selected layout along the outside edge of each leg of the trench. In an exemplary embodiment, the pFET and nFET share a common gate portion 7 as shown in FIG. 1.

The nFET transistor 22 may include tensile strain portions 91. In an exemplary embodiment, the tensile strain portions 91 may be arranged in an array running parallel with the edges of the STI trench 4, for example in a line parallel with the edges of the STI trench 4. In an exemplary embodiment, the nFET transistor 22 may include tensile strain portions 91 along each side of the STI trench 4.

The pFET transistor 21 may include tensile strain portions 91 and compressive strain portions 92. In an exemplary embodiment, the tensile strain portions 91 of the pFET may run along sides of the STI trench 4 that are approximately perpendicular with the gate 7. The compressive strain portions 92 may be arranged along sides of the STI trench 4 that run approximately parallel with the gate portion 7.

In an exemplary embodiment, the nFET 22 may be formed alongside the pFET 21.

FIG. 2 illustrates an exemplary embodiment of a method 30 for providing tensile and compressive strain in a silicon substrate. In an exemplary embodiment, the tensile and compressive strain may be interlocking strain. In an exemplary embodiment, the method 30 may be used in fabricating a pFET/nFET pair for use as an inverter 1 (FIG. 1).

The method 30 may include providing a silicon substrate. In an exemplary embodiment, the method includes providing the source, drain and gate for both an nFET and pFET, respectively. In an exemplary embodiment, the nFET and pFET may be arranged in close proximity to one another. In an exemplary embodiment, providing the source, drain and gate may be performed after the formation of the trenches. However, in an alternative embodiment of the invention, the source, drain and gate may be formed before the formation of the trenches.

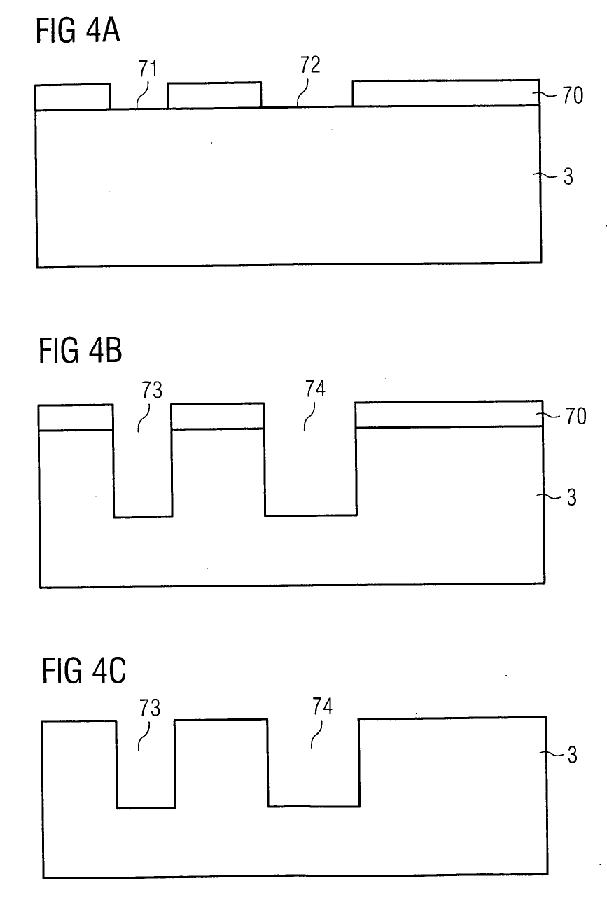

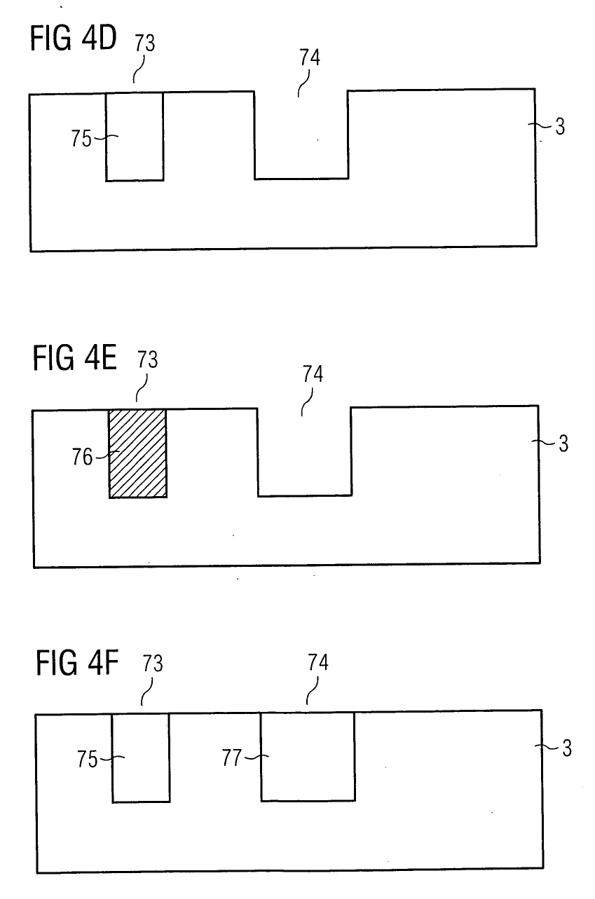

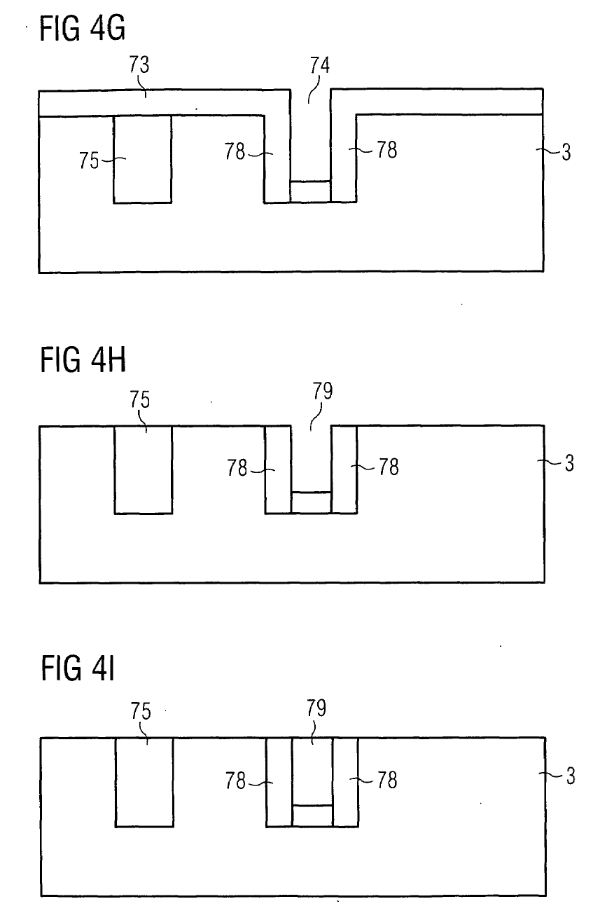

In an exemplary embodiment as shown by step 31, the method may include providing strain holes (see FIG. 4B). In an exemplary embodiment, providing strain holes may include deep trench etching. In an exemplary embodiment, the deep trench etch may be used to form holes in a surface of the silicon.

In an exemplary embodiment, providing the holes may include providing tensile strain holes and providing compressive strain holes (as noted by regions 32 and 33 in FIG. 2). In an exemplary embodiment, providing the holes may include providing holes in one etch step using a mask having different sized openings for different-sized strain holes. In an exemplary embodiment, the mask may form tensile strain holes that are smaller in diameter than the compressive strain holes.

In an exemplary embodiment, the tensile strain holes may be etched such that they are bigger than the compressive strain holes, which are etched as well.

However, in an alternative embodiment of the invention, the tensile strain holes may be etched such that they have the same size as or are smaller than the compressive strain holes. In this embodiment of the invention, the tensile strain holes would be etched first, then filled and after the filling of the tensile strain holes, the compressive strain holes would be etched.

In another exemplary embodiment of the invention, the tensile strain holes and the compressive strain holes may be etched at the same time (and may optionally have the same size). In this case, a mask is used for defining a first type of holes (the compressive strain holes), which should not be filled with the tensile material. Using the mask, the still exposed holes are filled with the tensile material. Next, the holes that have been covered by means of the mask are opened and the thus exposed holes are then filled with compressive material.

Referring back to the embodiment shown in FIG. 2, the different-sized holes may be provided in a position where a shallow trench isolation (STI) trench may subsequently be provided (step 34), for example, etched. In an exemplary embodiment, STI trench may be etched prior to etching the holes within the trench 4. In an alternative embodiment of the invention, the STI trench may be etched at the same time or after the etching of the holes.

The method 30 may include, in step 35, providing tensile material in the tensile strain holes. Providing tensile material in the tensile strain holes may include depositing SiN into the tensile strain holes. As an alternative tensile material, Al₂O₃ (optionally plus polysilicon), SiO₂, HfO₂, ZrO₂, W, TaN, TiSiN, TaSiN, Si:C (e.g., up to 1.5% or up to 10%) or TiN (optionally plus polysilicon) may be provided in the tensile strain holes. Furthermore, any combination of the above-mentioned materials can be used as the tensile material. Moreover, the deposition may be carried out using eptiaxy.

The method 30 may include, in step 36, providing compressive strain regions. In an exemplary embodiment, providing the compressive strain regions may include reoxidation (step 37) of polysilicon that has previously deposited into the compressive strain holes or depositing (step 38) compressive strain material into the compressive strain holes. Depositing compressive strain material may include depositing a compressive strain material into the compressive strain holes until a strain conversion has occurred. The compressive strain material may include epitaxial SiGe. In an exemplary embodiment, the compressive strain material may be deposited by means of chemical vapor deposition. As an alternative compressive material, carbon, SiO₂ (deposited or oxidized) or SiON may be provided

The method 30 further may include removing material from the surface, as indicated in step 39. Removing material from the surface may include an anisotropic trench etch.

The method 30 further may include filling the formed trench(es) with, for example, polysilicon. This is shown in step 40.

In an exemplary embodiment, the method 30 may include planarizing step 41. In an exemplary embodiment, planarizing may include using a chemical/mechanical polish (CMP) or an etch, e.g., a reactive ion etching.

In an exemplary embodiment, the substrate may further be processed according to known processes. These processes may include the formation of the STI, the well implantation, the formation of the gate, the source and the drain including spacers and possible source and drain extensions, the formation of passivation, contacts and the respective metal contacting layers.

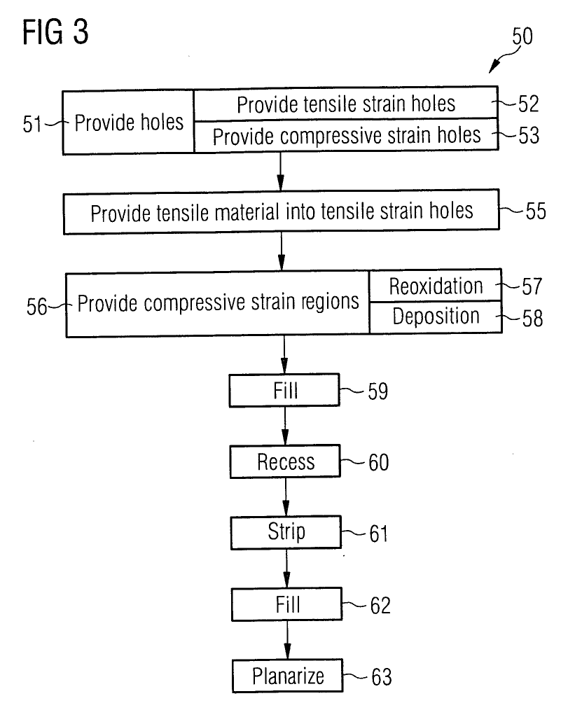

FIG. 3 illustrates an alternate exemplary embodiment of a method for fabricating an inverter. In an exemplary embodiment, the method 50 may include forming strain holes in a surface of a substrate, as shown in step 51. In an exemplary embodiment, forming the strain holes may include forming first strain type holes (box 52) and forming second strain type holes (box 53). The first strain type holes may be tensile strain holes and the second strain type holes may be compressive strain holes. The first and second strain type holes may be formed during a single etch with an etch mask having holes of different sizes. The tensile strain holes may be smaller in diameter than the compressive strain holes.

The method 50 may further include providing tensile portions, as shown in step 55. In an exemplary embodiment, providing tensile portions may include depositing tensile material in the tensile strain holes, e.g., by means of chemical vapor deposition, by means of oxidation, by means of atomic layer deposition or by means of changing the morphology of the layers, e.g., rapid thermal processing (RTP) steps.

The method 50 may include providing compressive portions, as shown in step 56. In an exemplary embodiment, providing the compressive portions may include either reoxidation (box 57) or depositing (box 58) compressive strain material. In an exemplary embodiment, the compressive strain material may comprise SiGe.

In an exemplary embodiment, the method 50 may include filling and recess steps 59 and 60. In an exemplary embodiment, filling may include filling with polysilicon. In an exemplary embodiment, recessing may include chemical mechanical polishing (CMP).

In an exemplary embodiment, the method 50 may include stripping the layer sequence in the large holes, e.g., the used hard mask or the used photoresist. This is illustrated by step 61.

The method 50 may include a second fill process 62, for example a polysilicon fill.

The method 50 may further include a planarizing step 63. In an exemplary embodiment, planarizing may include a CMP.

The substrate may further be processed according to a typical process, e.g., including the process steps as described above.

FIGS. 4A to 4F illustrate cross-sectional views of a surface of a substrate 3 at various stages of an exemplary embodiment of a method for forming interlocking strain portions on a surface of a substrate.

FIG. 4A illustrates an exemplary embodiment of a surface of a substrate 3 with a mask 70. The mask 70 may have strain portion openings 71, 72 corresponding to first and second strain type holes to be etched. In an exemplary embodiment, the opening 71 may be larger than the opening 72. In an exemplary embodiment, the opening 71 corresponds to a tensile strain hole 73 (FIG. 4B) to be etched and the opening 72 corresponds to a compressive strain hole 74 (FIG. 4B) to be etched.

FIG. 4B illustrates an exemplary embodiment of a surface of a substrate 3 after the first and second strain type holes 73, 74 have been etched through a mask. In an exemplary embodiment, the hole 73 may be a tensile strain hole corresponding to a tensile portion 91 to be formed and the hole 74 may be a compressive strain hole corresponding to a compressive strain portion 92 to be formed.

FIG. 4C illustrates an exemplary embodiment of a surface of a substrate 3 after the mask 70 has been stripped.

FIG. 4D illustrates an exemplary embodiment of a surface of a substrate 3 after tensile strain material 75 has been deposited in the hole 73. For example, polysilicon can be deposited in the hole 73.

FIG. 4E illustrates an exemplary embodiment of a surface of a substrate 3 after the filling material (i.e., for example the polysilicon) has been reoxidized, thereby forming reoxidized tensile strain material 76. In other embodiments, other materials and/or techniques can be used to generate strain.

FIG. 4F illustrates an alternate exemplary embodiment of a surface of a substrate 3 after compressive strain material 77 has been deposited into the compressive strain hole 74. In an exemplary embodiment, the compressive strain material 77 is deposited by chemical vapor deposition. As discussed above, the comprehensive strain material 77 can be SiGe, SiO₂ and/or SiON.

FIG. 4G illustrates an exemplary embodiment of a substrate after an anisotropic “spacer” etch, wherein spacers 78 are formed from the compressive strain material 77 in the compressive strain hole 74.

FIG. 4H illustrates an exemplary embodiment of a substrate 3 after a fill. In an exemplary embodiment, the fill material 79 may be polysilicon.

FIG. 4I illustrates an exemplary embodiment of a substrate after the surface has been planarized. In an exemplary embodiment, the surface may be planarized by a CMP or an etch. In an exemplary embodiment, the substrate may have first and second strain type portions 91, 92, for example a tensile strain portion 91 and a compressive strain portion 92. In an exemplary embodiment, the tensile strain portion may include a plurality of individual tensile strain portions or regions aligned in a row or column, as illustrated in FIG. 1. The compressive strain portion 92 may include a plurality of individual compressive strain portions or regions aligned in a row or column as illustrated in FIG. 1. In an exemplary embodiment, the tensile strain portion 91 may be aligned in an orientation perpendicular to an orientation of a gate portion and the compressive strain portion may be oriented in an orientation parallel with a gate portion, as illustrated in FIG. 1.

In an exemplary embodiment, the tensile strain holes 73, 74 for the tensile strain portion 91 and the compressive strain portion 92 for both an nFET and a pFET of an inverter pair of transistors may be formed in a common etch step.

It should be noted that the above-described processes can also be provided for only nFETs or for only pFETs. Thus, any arbitrary transistor arrangement can be formed in this way and the invention is not limited to the formation of an inverter.

Although the foregoing has been a description and illustration of specific embodiments of the invention, various modifications and changes thereto can be made by persons skilled in the art without departing from the scope and spirit of the invention as defined by the following claims.

In one embodiment of the invention, the stress conversion from tensile stress to compressive stress is achieved by providing TiN and polysilicon into the holes and then oxidizing the materials in the respective holes. This reaction results in TiN and SiO₂.

In another embodiment of the invention, the stress conversion from tensile stress to compressive stress is achieved by providing SiN into the holes and then oxidizing the SiN in the respective holes. This reaction results in SiON.

In yet another embodiment of the invention, the stress conversion from tensile stress to compressive stress is achieved by providing Al₂O₃ and polysilicon into the holes and then oxidizing the materials in the respective holes. This reaction results in Al₂O₃ and SiO₂.

In one embodiment of the invention, the stress conversion from compressive stress to tensile stress is achieved by providing carbon into small holes and into larger holes and then ashing the carbon. The ashed carbon will be pulled back into the smaller holes. Furthermore, the carbon in the larger holes will be removed completely.

What is claimed is:

1. A transistor, comprising:
a silicon substrate; and
a trench portion formed at a surface of the silicon substrate;
wherein the silicon substrate includes:
a first strain type portion oriented in a first direction; and
a second strain type portion oriented in a second direction.

2. The transistor according to claim 1, wherein the first strain type portion comprises a tensile strain type portion and the second strain type portion comprises a compressive strain type portion.

3. The transistor according to claim 1, further comprising a gate region, wherein the gate region is oriented in a direction substantially perpendicular with the first direction and substantially parallel with the second direction.

4. The transistor according to claim 3, wherein the first strain type portion comprises a tensile strain type portion and the second strain type portion comprises a compressive strain type portion.

5. The transistor according to claim 1, wherein the first strain type portion comprises at least one first trench and the second strain type portion comprises at least one second trench.

6. The transistor according to claim 5, wherein the at least one first trench has a different size than the at least one second trench.

7. A semiconductor device comprising:
a silicon substrate;
a first transistor disposed in a first active area of the substrate, wherein the first active area surrounded by a first quadrilateral trench, wherein the first trench comprises first and second sides arranged in a first direction and third and fourth sides arranged in a second direction, the second direction being substantially perpendicular to the first direction;
a second transistor disposed in a second active area of the substrate, wherein the second active area is surrounded by a second quadrilateral trench, wherein the second trench comprises fifth and sixth sides arranged in the first direction and seventh and eighth sides arranged in the second direction;
a gate region overlying the first and second active areas, the gate region being arranged in a direction substantially parallel with the first direction;
tensile strained regions adjacent the first, second, third, fourth, fifth and sixth sides; and
compressive strained regions adjacent the seventh and eighth sides.

8. The semiconductor device according to claim 7, wherein the first transistor comprises an n-channel transistor.

9. The semiconductor device according to claim 7, wherein the second transistor comprises a p-channel transistor.

10. The semiconductor device according to claim 7, further comprising a plurality of trenches arranged in the substrate in a plurality of adjacent rows.

11. The semiconductor device according to claim 10, wherein the plurality of trenches are arranged in a direction substantially parallel with the first direction.

12. A method of forming a semiconductor device, the method comprising:
providing a mask at a surface of a substrate, wherein the mask comprises a first plurality of openings corresponding to a first plurality of holes to be etched and a second plurality of openings corresponding to a second plurality of holes to be etched;
etching the surface of the substrate through the mask to form the first and second pluralities of holes;
depositing a first strain type material into the first plurality of holes to form a plurality of first strain type portions; and
forming a plurality of second strain type portions at the second plurality of holes.

13. The method according to claim 12, wherein the plurality of first strain type portions comprises a plurality of tensile strain portions and wherein the plurality of second strain type portions comprises a plurality of compressive strain portions.

14. The method according to claim 12, wherein depositing the first strain type material comprises depositing at least one material selected from the group consisting of SiN, Al₂O₃ plus polysilicon, TiN, TiN plus polysilicon, HfO₂, ZrO₂, W, TaN, TiSiN, TaSiN, or Si:C, and combinations thereof.

15. The method according to claim 12, wherein forming a plurality of second strain type portions comprises reoxidizing the substrate.

16. The method according to claim 12, wherein forming a plurality of second strain type portions comprises depositing a second strain type material in the plurality of second strain type holes.

17. The method according to claim 16, wherein the second strain type material comprises a material selected from the group consisting of SiGe, C, SiO₂ and SiON and combinations thereof.

18. A method for fabricating a transistor, the method comprising:
forming a source region, a drain region in a semiconductor body and a gate region overlying the semiconductor body, wherein the gate region is oriented in a first direction and the source region and the drain region are arranged on laterally opposed sides of the gate with respect to the first direction;
forming a shallow trench isolation (STI) trench, wherein at least a first portion of the trench is oriented parallel with the first direction and at least a second portion of the trench is oriented perpendicular to the first direction;
providing a first strain type portion, wherein the first strain type portion is oriented in a direction parallel with first portion of the trench; and
providing a second strain type portion, wherein the second strain type portion is aligned perpendicular with the second portion of the trench.

19. The method in accordance with claim 18, wherein the shallow trench isolation (STI) trench is a quadrilateral and the first and second portions of the trench are sides of the quadrilateral.

20. The method in accordance with claim 18, wherein the first strain type portion comprises a compressive strain portion and the second strain type portion comprises a tensile strain portion.

21. The method in accordance with claim 18, wherein the transistor comprises a p-channel transistor.

22. The method in accordance with claim 18, further comprising deep trench etching the surface of the substrate to form a first plurality of holes and a second plurality of holes.

23. The method of claim 22, wherein the first plurality of holes have diameters greater than diameters of the second plurality of holes.

24. The method of claim 22, further comprising depositing a tensile strain material in the second plurality of holes.

25. The method of claim 22, further comprising depositing a compressive strain material in the first plurality of holes.

26. The method of claim 22, further comprising reoxidizing the substrate to provide compressive strain at the first plurality of holes.
